(19) United States
(12) Patent Application Publication
(10) Pub. No.: US 2026/0247949 A1
(43) Pub. Date: Aug. 20, 2026

(54) SEMICONDUCTOR DEVICE

(71) Applicant: Socionext Inc., Kanagawa (JP)

(72) Inventors: Atsushi OKAMOTO, Yokohama (JP); Hirotaka TAKENO, Yokohama (JP); Wenzhen WANG, Yokohama (JP)

(21) Appl. No.: 19/643,199

(22) Filed: Apr. 9, 2026

Related U.S. Application Data
(63) Continuation of application No. PCT/JP2023/037172, filed on Oct. 13, 2023.

(51) Int. Cl. H10W 20/41; H10W 20/43; H03K 17/10; H10D 30/00; H10D 30/43; H10D 84/01; H10D 84/85

(52) U.S. Cl. CPC H10W 20/427; H10W 20/43; H10W 20/435; H03K 17/102; H10D 30/43; H10D 30/502; H10D 84/0186; H10D 84/851

(57) ABSTRACT

A semiconductor device includes a substrate; a first power line, a second power line, and a third power line formed in the substrate; a first semiconductor layer and a second semiconductor layer formed above the substrate; a third semiconductor layer formed above the first semiconductor layer; a fourth semiconductor layer formed above the second semiconductor layer; a first gate formed between the first semiconductor layer and the second semiconductor layer and between the third semiconductor layer and the fourth semiconductor layer; and a switch transistor formed between the first power line and the second power line, the switch transistor including the first semiconductor layer, the second semiconductor layer, and the first gate, or including the third semiconductor layer, the fourth semiconductor layer, and the first gate.

### CROSS-REFERENCE TO RELATED APPLICATION

This application is a continuation application of International Application PCT/JP2023/037172 filed on October 13, 2023 and designated the U.S., the entire contents of which are incorporated herein by reference.

### FIELD

The embodiments discussed herein are related to a semiconductor device.

### BACKGROUND

A CFET (Complementary Field Effect Transistor) technology in which transistors are formed in a stacked manner is known. A BPR (Buried Power Rail) technology is known in which a buried interconnect formed by forming a conductor in a trench formed in a surface of a semiconductor substrate is used to supply a power supply potential or a ground potential to a transistor. A technology is known in which a power switch circuit that controls turning on and off of supply of a power supply potential is provided in a standard cell or the like.

Patent Document 1: U.S. Patent Application Publication No. 2023/0178435

Patent Document 2: U.S. Patent Application Publication No. 2023/0067311

Patent Document 3: U.S. Patent Application Publication No. 2022/0123023

Patent Document 4: U.S. Patent Application Publication No. 2022/0181258

Patent Document 5: International Publication No. WO 2020/065916

Patent Document 6: International Publication No. WO 2020/066797

Patent Document 7: International Publication No. WO 2020/217396

Patent Document 8: International Publication No. WO 2020/217400

Patent Document 9: U.S. Patent Application Publication No. 2021/0366902

Patent Document 10: U.S. Patent Application Publication No. 2022/0102479

Patent Document 11: U.S. Patent Application Publication No. 2021/0210600

### SUMMARY

According to an aspect of an embodiment, a semiconductor device includes:

a substrate;

a first power line, a second power line, and a third power line formed in the substrate;

a first semiconductor layer and a second semiconductor layer formed above the substrate;

a third semiconductor layer formed above the first semiconductor layer;

a fourth semiconductor layer formed above the second semiconductor layer;

a first gate formed between the first semiconductor layer and the second semiconductor layer and between the third semiconductor layer and the fourth semiconductor layer; and

a switch transistor formed between the first power line and the second power line, the switch transistor including the first semiconductor layer, the second semiconductor layer, and the first gate, or including the third semiconductor layer, the fourth semiconductor layer, and the first gate.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a plan view illustrating an example of a layout of a semiconductor device in a first embodiment;

FIG. 2 is a cross-sectional view illustrating an example of a cross-sectional structure of the semiconductor device of FIG. 1;

FIG. 3 is a circuit diagram illustrating an example of a circuit disposed in a standard cell block of FIG. 1;

FIG. 4 is a circuit diagram illustrating an example of the power switch circuit of FIG. 3;

FIG. 5 is a perspective view illustrating an example of a layout of the power switch circuit and a standard cell of FIG. 3;

FIG. 6 indicates perspective views illustrating examples of a method for connecting a top interconnect and an interconnect of a BPR layer formed in a substrate;

FIG. 7 is a plan view illustrating an example of a plan view of the substrate SUB viewed from a top interconnect side in the power switch circuit and the standard cell of FIG. 5;

FIG. 8 is a plan view illustrating an example of a plan view of the substrate SUB side viewed from a bottom interconnect side in the power switch circuit and the standard cell of FIG. 5;

FIG. 9 is a cross-sectional view illustrating an example of a cross-section taken along line X1-X1’ of FIGS. 7 and 8;

FIG. 10 is a cross-sectional view illustrating an example of a cross-section taken along line X2-X2’ of FIGS. 7 and 8;

FIG. 11 is a cross-sectional view illustrating an example of a cross-section taken along line Y1-Y1’ of FIGS. 7 and 8;

FIG. 12 is a perspective view illustrating an example of a layout of a power switch circuit and a standard cell in a second embodiment;

FIG. 13 is a circuit diagram illustrating an example of a power switch circuit and a standard cell in a third embodiment;

FIG. 14 is a perspective view illustrating an example of a layout of the power switch circuit and the standard cell of FIG. 13;

FIG. 15 is a plan view illustrating an example of a plan view of the substrate SUB viewed from the top interconnect side in the power switch circuit and the standard cell of FIG. 14;

FIG. 16 is a plan view illustrating an example of a plan view of the substrate SUB side viewed from the bottom interconnect side in the power switch circuit and the standard cell of FIG. 14;

FIG. 17 is a circuit diagram illustrating an example of a power switch circuit and a standard cell in a fourth embodiment;

FIG. 18 is a perspective view illustrating an example of a layout of the power switch circuit and the standard cell of FIG. 17;

FIG. 19 is a circuit diagram illustrating an example of a power switch circuit and a standard cell in a fifth embodiment; and

FIG. 20 is a perspective view illustrating an example of a layout of the power switch circuit and the standard cell of FIG. 19.

### DESCRIPTION OF EMBODIMENTS

In a case where a power switch circuit is formed by connecting a source or a drain of a CFET to a buried power rail (BPR) interconnect, detailed studies have not been made on layout configurations for the power switch circuit.

The present disclosure has been made in view of the above circumstances, and an objective of the present disclosure is to provide an appropriate layout for a power switch circuit formed using a CFET whose source and drain are connected to a BPR interconnect.

According to the disclosed technology, a power switch circuit formed using a CFET in which a source and a drain are connected to a BPR interconnect can be appropriately laid out.

Embodiments will be described below with reference to the drawings. In the following, reference numerals indicating signals are also used as reference numerals indicating signal lines or signal terminals. Reference numerals indicating power supply potentials are also used as reference numerals indicating power supply lines or power supply terminals to which the power supply potentials are supplied.

### First Embodiment

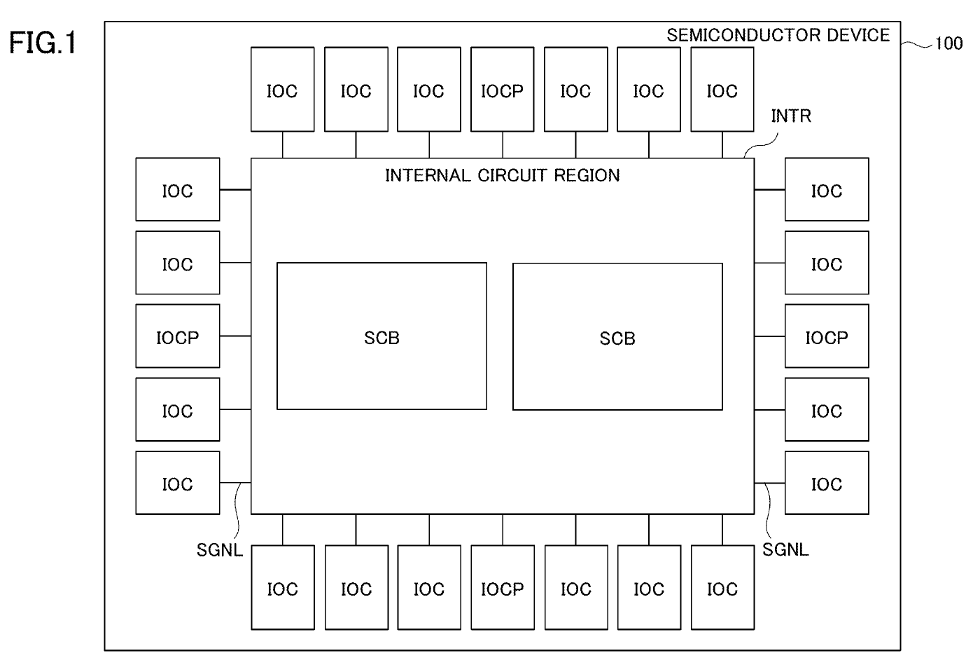

FIG. 1 illustrates an example of a layout of a semiconductor device 100 in the first embodiment. For example, the semiconductor device 100 illustrated in FIG. 1 may be an SoC (System on Chip), or may be a single FPGA (Field-Programmable Gate Array) or the like.

The semiconductor device 100 includes a plurality of I/O cells IOC and IOCP, and an internal circuit region INTR. The I/O cell IOC is an interface circuit for a signal SGNL, such as an input signal, an output signal, or an input/output signal. The I/O cell IOCP is an interface circuit for a power supply potential or a ground potential.

Each of the I/O cells IOC and IOCP is connected to the internal circuit region INTR. For example, the internal circuit region INTR includes one or more standard cell blocks SCB in which standard cells are provided. In addition, a logic circuit other than a standard cell may be provided in the internal circuit region INTR, or a memory may be provided in the internal circuit region INTR. The memory may be provided in the standard cell block SCB.

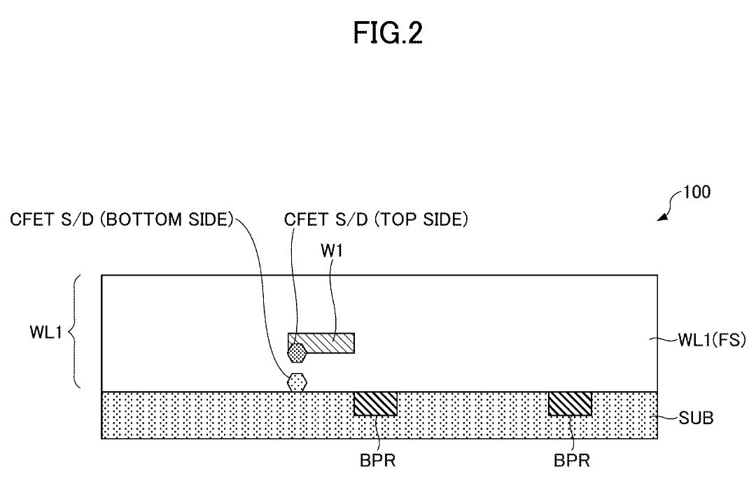

FIG. 2 illustrates an example of a cross-sectional structure of the semiconductor device 100 of FIG. 1. The semiconductor device 100 includes a substrate SUB and an interconnect layer WL1 formed on a surface FS of the substrate SUB. On the surface FS of the substrate SUB, a source/drain region S/D, which is part of a CFET, is formed on a bottom side closer to the substrate SUB, and is also formed on a top side farther from the substrate SUB. The source/drain region S/D of the CFET may be connected to an interconnect W1 formed in the interconnect layer WL1. A trench is formed on the surface FS of the substrate SUB, and a buried conductive interconnect BPR is formed in the trench.

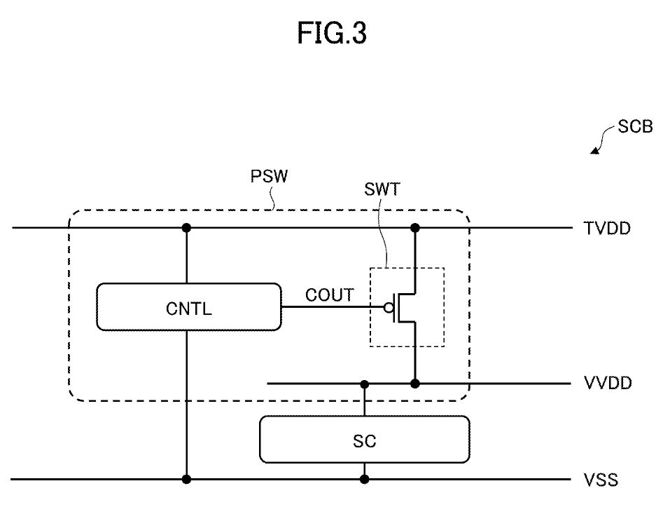

FIG. 3 illustrates an example of a circuit disposed in the standard cell block SCB of FIG. 1. The standard cell block SCB includes a power switch circuit PSW and a standard cell SC. The standard cell SC is connected to a virtual power line VVDD and a ground line VSS, and operates by receiving a supply of a virtual power supply potential VVDD from the virtual power line VVDD. The standard cell SC has various logic circuits.

The power switch circuit PSW operates while being connected to a power line TVDD and the ground line VSS. The power switch circuit PSW includes a control circuit CNTL and a switch transistor SWT. For example, the control circuit CNTL generates a control signal COUT that controls the switch transistor SWT in accordance with an input signal (not illustrated). The power line TVDD is an example of a first power line, the virtual power line VVDD is an example of a second power line, and the ground line VSS is an example of a third power line.

The switch transistor SWT includes a PMOS transistor having a source connected to the power line TVDD and a drain connected to the virtual power line VVDD, and operates by receiving a voltage of the control signal COUT from the control circuit CNTL as a gate potential. While the switch transistor SWT is on, the power line TVDD and the virtual power line VVDD are electrically connected, and the power supply potential TVDD is supplied to the standard cell SC via the virtual power line VVDD. While the switch transistor SWT is off, the electrical connection between the power line TVDD and the virtual power line VVDD is cut off, and the virtual power line VVDD is set to a floating state.

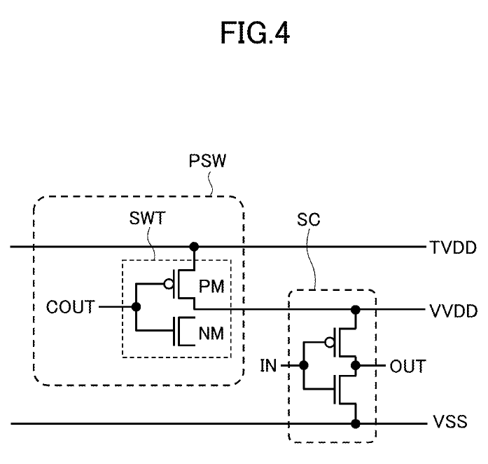

FIG. 4 illustrates an example of a circuit of the power switch circuit PSW of FIG. 3. The power switch circuit PSW includes a switch transistor SWT including a PMOS transistor PM and an NMOS transistor NM. In the PMOS transistor PM, a source is connected to the power line TVDD and a drain is connected to the virtual power line VVDD. In the NMOS transistor NM, both a source and a drain are floating. The gates of the PMOS transistor PM and the NMOS transistor NM receive the control signal COUT output from the control circuit CNTL in FIG. 3. Note that the source and the drain of the NMOS transistor NM of the power switch circuit PSW may be set to be floating while being interconnected by an interconnect.

FIG. 4 illustrates an example in which the standard cell SC includes an inverter disposed between the virtual power line VVDD and the ground line VSS. For example, transistors of the power switch circuit PSW and the standard cell SC are CFETs.

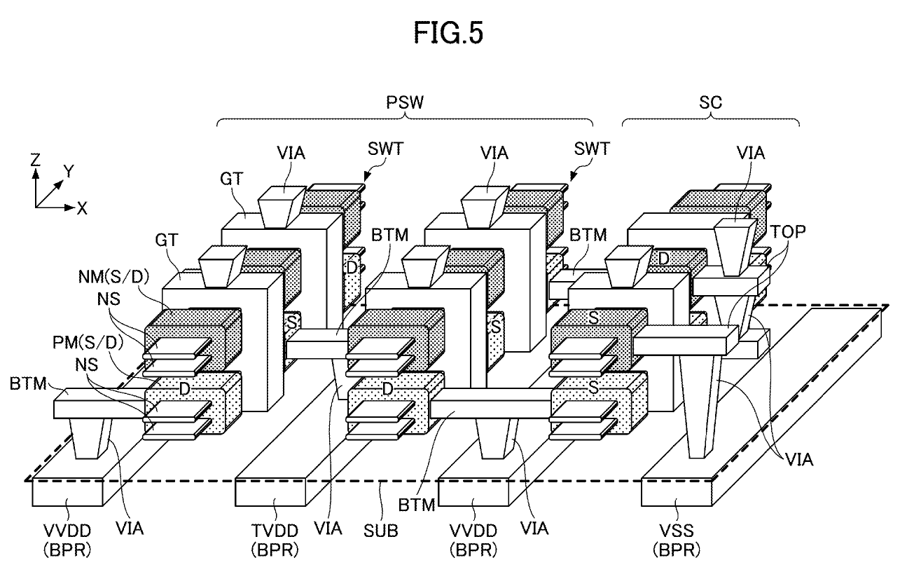

FIG. 5 illustrates an example of a layout of the power switch circuit PSW and the standard cell SC illustrated in FIG. 3. In FIG. 5, illustration of interlayer insulating films is omitted, and the substrate SUB is schematically indicated by thick broken lines. In the layout illustrated in FIG. 5, bottom-side semiconductor layers disposed above the substrate SUB are formed as a source/drain region S/D of a PMOS transistor PM of a CFET, and top-side semiconductor layers disposed above the bottom-side semiconductor layers are formed as a source/drain region S/D of an NMOS transistor NM of the CFET. In the CFET, two bottom-side semiconductor layers are interconnected by nanosheets NS, and two top-side semiconductor layers are interconnected by top-side nanosheets NS. In the CFET, a gate of the PMOS transistor and a gate of the NMOS transistor are common. The source/drain region S/D of the NMOS transistor NM has an N-type conductivity, and the source/drain region S/D of the PMOS transistor PM has a P-type conductivity. In the present disclosure, a semiconductor layer may be referred to as a source/drain region S/D even when the transistor does not function as a transistor. In addition, a part of a CFET structure may be referred to as an NMOS transistor NM or a PMOS transistor PM according to a conductivity type of the semiconductor layer, even when the transistor does not function as a transistor.

Reference signs S and D assigned to the source/drain region S/D of the NMOS transistor NM and the PMOS transistor PM respectively indicate a source and a drain of each transistor. The source/drain region S/D of the NMOS transistor NM to which neither reference sign S nor D is assigned is, for example, in an open state, indicating that the transistor does not function as a transistor.

In FIG. 5, in the power switch circuit PSW, each of a PMOS transistor group and an NMOS transistor group is disposed in the order of drain, gate, source, gate, and drain along a Y direction. The Y direction is an example of a first direction. As illustrated in FIG. 4, the source and the drain of the NMOS transistor of the switch transistor SWT are in an open state.

The PMOS transistor group and the NMOS transistor group of the power switch circuit PSW are disposed above the substrate SUB at positions corresponding to between the power line TVDD and the virtual power line VVDD of the BPR layer in a plan view. That is, the PMOS transistor group and the NMOS transistor group of the power switch circuit PSW are disposed at offset positions in an X direction in a plan view with respect to the power line TVDD and the virtual power line VVDD of the BPR layer. The X direction is an example of a second direction.

In the power switch circuit PSW, the source of the PMOS transistor of the switch transistor SWT is connected to the power line TVDD of the BPR layer via a bottom interconnect BTM extending in the X direction and a via VIA. The drain of the PMOS transistor of the switch transistor SWT is connected to the virtual power line VVDD of the BPR layer via the bottom interconnect BTM extending in the X direction and the via VIA. The bottom interconnect BTM and the PMOS transistor on the substrate SUB side (bottom side) in the CFET have a portion with the same position in the Z direction.

In the standard cell SC, the source of the NMOS transistor is connected to the ground line VSS of the BPR layer via a top interconnect TOP extending in the X direction and a via VIA. In the standard cell SC, the drain of the NMOS transistor is connected to an upper layer interconnect (not illustrated) via the top interconnect TOP extending in the X direction and a via VIA. In addition, in the standard cell SC, the drain of the NMOS transistor is connected to the bottom interconnect BTM via the via VIA. The top interconnect TOP and the transistor on the opposite side (top side) to the substrate SUB in the CFET have a portion with the same position in the Z direction.

In the standard cell SC, the source of the PMOS transistor is connected to the virtual power line VVDD of the BPR layer via the bottom interconnect BTM extending in the X direction and shared with the drain D of the PMOS transistor PM of the power switch circuit PSW, and via the via VIA. In the standard cell SC, the drain of the PMOS transistor is connected to the top interconnect TOP via the bottom interconnect BTM extending in the X direction and the via VIA. Note that in the PMOS transistor and the NMOS transistor of the standard cell SC, the gate and the source on the far side in the Y direction in FIG. 5 are set to an open state and are not used.

In the switch transistor SWT and the standard cell SC, the gate GT of each transistor is connected to an upper layer interconnect (not illustrated) via a via VIA formed on the gate GT. The gate GT of the switch transistor SWT is an example of a first gate.

In FIG. 5, a virtual power supply line VVDD in a BPR layer located at a boundary between the power switch circuit PSW and the standard cell SC is commonly connected to the power switch circuit PSW and the standard cell SC; however, separate virtual power supply lines VVDD may be provided for the power switch circuit PSW and the standard cell SC. In addition, in the power switch circuit PSW, positions of a power supply line TVDD in the BPR layer and the virtual power supply line VVDD may be interchanged with each other.

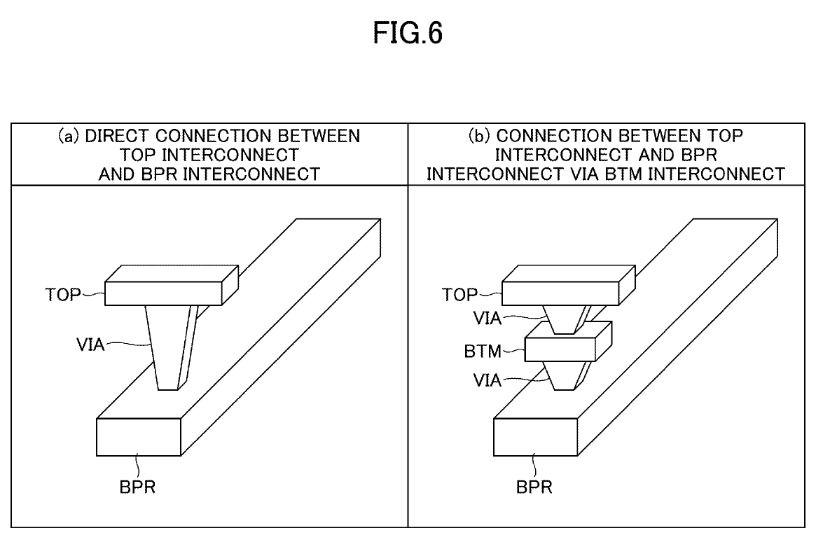

FIG. 6 illustrates examples of a method for connecting the top interconnect TOP and the interconnect of the BPR layer formed in the substrate SUB. As illustrated in (a) of FIG. 6, the top interconnect TOP and the interconnect of the BPR layer may be directly connected by the via VIA without passing through the bottom interconnect BTM, similar to the interconnect of the standard cell SC in FIG. 5. As illustrated in (b) of FIG. 6, the top interconnect TOP and the interconnect of the BPR layer may be connected via the bottom interconnect BTM. Note that the interconnect method of (b) of FIG. 6 may be applied in other embodiments.

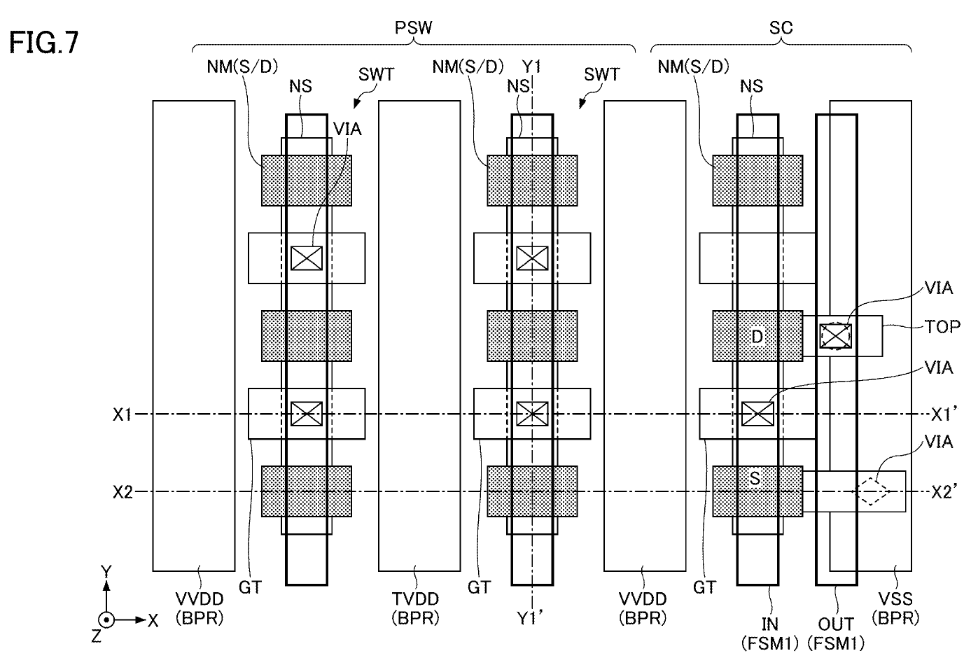

FIG. 7 is a plan view illustrating an example of the power switch circuit PSW and the standard cell SC of FIG. 5, viewed from the top interconnect TOP side toward the substrate SUB side. In FIG. 7, a source and a drain of an NMOS transistor NM to which neither reference sign S nor D is assigned are in an open state, indicating that the NMOS transistor NM does not function as a transistor.

An interconnect indicated by a thick solid line extending in the Y direction indicates an interconnect of an interconnect layer FSM1 (FSM is an abbreviation for Frontside Metal) disposed on the upper side (the side toward the position where the CFET is disposed from the substrate SUB in the Z direction) of the switch transistor SWT and the standard cell SC. The interconnect of the interconnect layer FSM1 is located above the top interconnect TOP and is formed using any one of a plurality of interconnect layers on the top interconnect TOP.

The NMOS transistors NM of the power switch circuit PSW and the standard cell SC are disposed at offset positions in the X direction in a plan view with respect to the power line TVDD, the virtual power line VVDD, and the ground line VSS of the BPR layer. The source and the drain of the NMOS transistor NM are disposed at positions corresponding to a formation region of the top interconnect TOP in the Z direction. The source and the drain of the NMOS transistor NM are disposed on both sides of the gate GT in the Y direction.

In the NMOS transistor NM of the power switch circuit PSW, one of the source and the drain is an example of one of a third semiconductor layer and a fourth semiconductor layer, and the other of the source and the drain is an example of the other of the third semiconductor layer and the fourth semiconductor layer.

When an inverter is formed in the standard cell SC, a drain D of the NMOS transistor NM of the inverter is connected to an output signal line OUT of the interconnect layer FSM1 via the top interconnect TOP and an upper via VIA, and is connected to the bottom interconnect BTM via the top interconnect TOP and a lower via VIA. Hereinafter, the interconnect layer FSM1 is also referred to as an FSM1 layer. A source S of the NMOS transistor NM of the inverter is connected to the ground line VSS of the BPR layer via the top interconnect TOP and a via VIA on the bottom interconnect BTM side. A gate of the inverter is connected to an input signal line IN of the FSM1 layer via a via VIA.

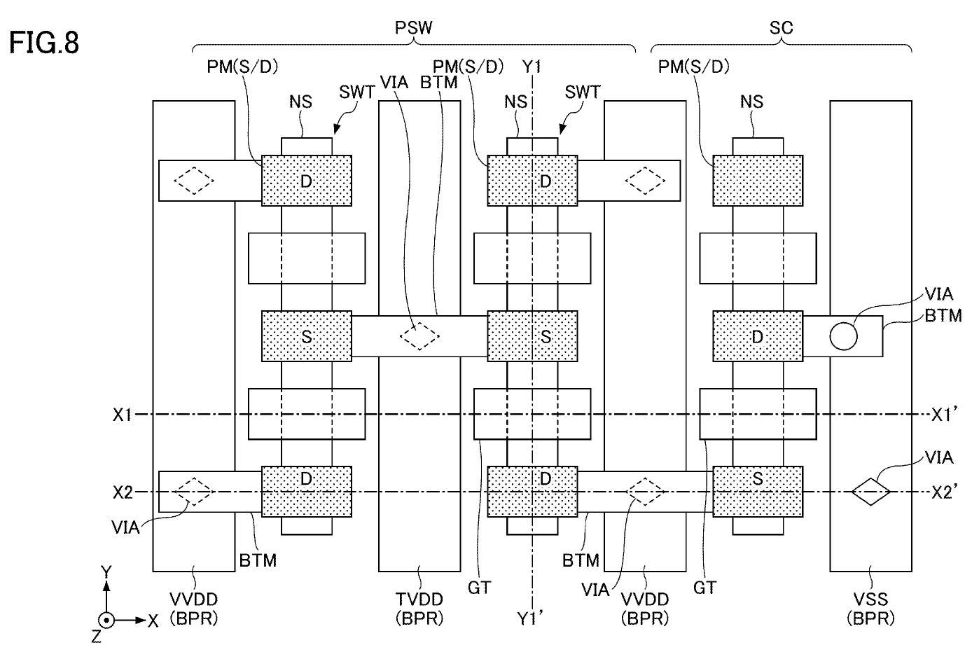

FIG. 8 is a plan view illustrating an example of the power switch circuit PSW and the standard cell SC of FIG. 5, viewed from the bottom interconnect BTM side toward the substrate SUB side. In FIG. 8, a source and a drain of a PMOS transistor PM to which neither reference sign S nor D is assigned are in an open state, indicating that the PMOS transistor PM does not function as a transistor.

The PMOS transistors PM of the power switch circuit PSW and the standard cell SC are disposed at offset positions in the X direction in a plan view with respect to the power line TVDD, the virtual power line VVDD, and the ground line VSS of the BPR layer. The source and the drain of the PMOS transistor PM are disposed at positions corresponding to a formation region of the bottom interconnect BTM in the Z direction. The source and the drain of the PMOS transistor PM are disposed on both sides of the gate GT in the Y direction.

In the PMOS transistor PM of the power switch circuit PSW, one of the source and the drain is an example of one of a first semiconductor layer and a second semiconductor layer, and the other of the source and the drain is an example of the other of the first semiconductor layer and the second semiconductor layer.

In the power switch circuit PSW, the source S of the PMOS transistor PM is connected to the power line TVDD of the BPR layer via the bottom interconnect BTM and the via VIA. The drain D of the PMOS transistor PM is connected to the virtual power line VVDD of the BPR layer via the bottom interconnect BTM and the via VIA.

As illustrated in FIG. 8, when the switch transistor SWT has a plurality of PMOS transistors PM, sources S of the plurality of PMOS transistors PM may be connected to the power line TVDD of the BPR layer via a common bottom interconnect BTM. Further, when the virtual power line VVDD of the BPR layer is disposed between columns of the PMOS transistors PM formed with an interval in the X direction in a plan view, drains D of the plurality of columns of the PMOS transistors PM may be connected to the virtual power line VVDD of the BPR layer via a common bottom interconnect BTM. Accordingly, the number of bottom interconnects BTM connected to the drain D of the PMOS transistor PM can be reduced.

When an inverter is formed in the standard cell SC, a drain D of the PMOS transistor PM is connected to the drain D of the NMOS transistor NM and the output signal line OUT of FIG. 7 via the bottom interconnect BTM and the via VIA. A source S of the PMOS transistor PM of the inverter is connected to the virtual power line VVDD of the BPR layer via the bottom interconnect BTM and the via VIA.

In the example illustrated in FIG. 8, the bottom interconnect BTM connecting the source S of the PMOS transistor PM of the inverter to the virtual power line VVDD of the BPR layer is also connected to the drain D of the PMOS transistor PM of the switch transistor SWT. A common bottom interconnect BTM that interconnects the source S of the PMOS transistor PM of the inverter of the standard cell SC and the drain D of the PMOS transistor PM of the switch transistor SWT is an example of a fourth interconnect.

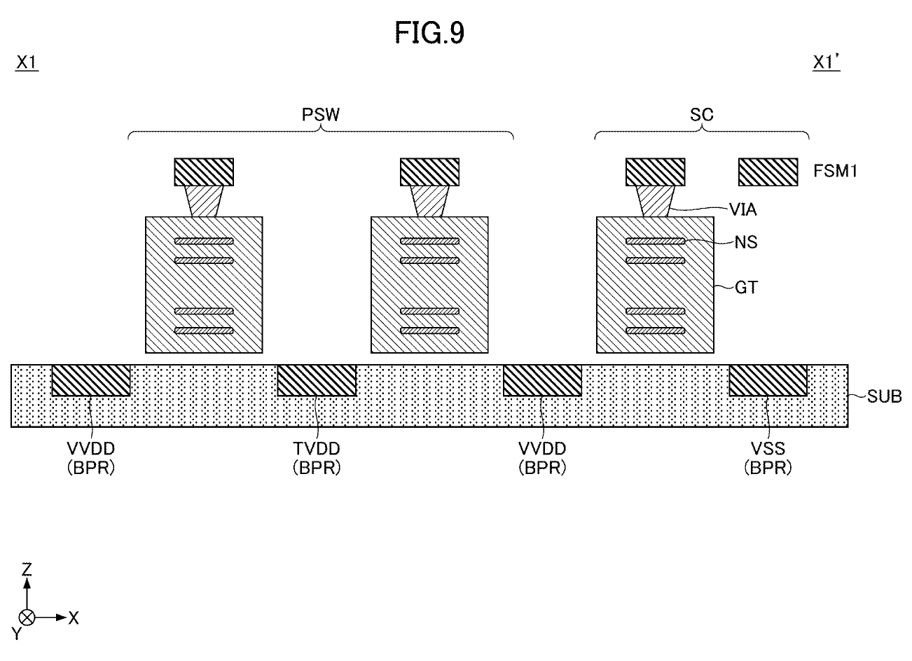

FIG. 9 illustrates an example of a cross-section taken along line X1-X1’ of FIGS. 7 and 8. The gate GT of each transistor is connected to an interconnect of the FSM1 layer via a via VIA. Further, the gate GT of each transistor is disposed above the substrate SUB via an insulating film, and is disposed between interconnects of the BPR layer disposed with an interval in the X direction. The nanosheets NS are provided through the gate GT.

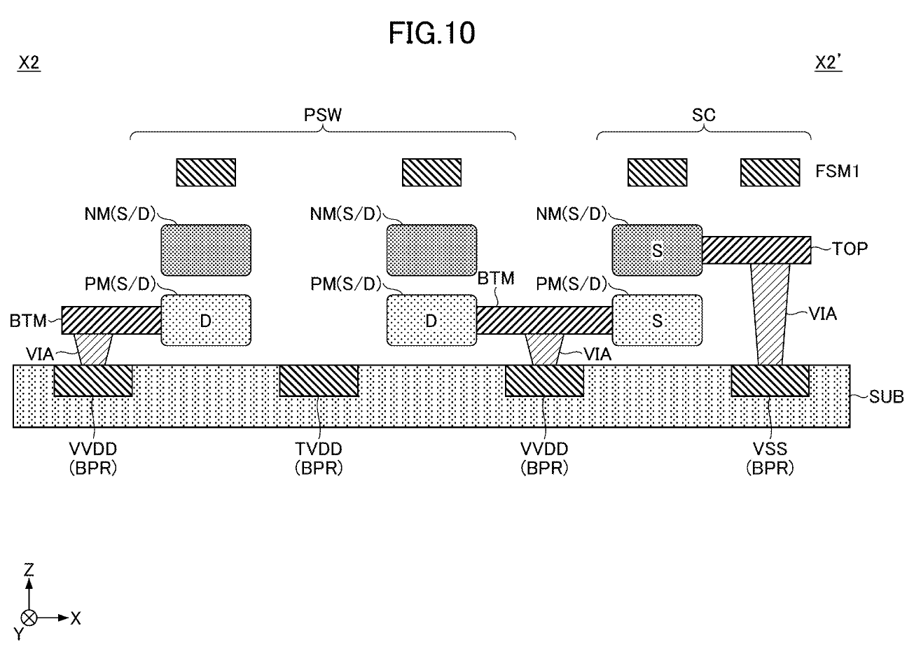

FIG. 10 illustrates an example of a cross-section taken along line X2-X2’ of FIGS. 7 and 8. In the power switch circuit PSW, the source/drain region S/D of the NMOS transistor NM is set to an open state, and the drain D of the PMOS transistor PM is connected to the virtual power line VVDD of the BPR layer via the bottom interconnect BTM and the via VIA.

In the standard cell SC, the source S of the NMOS transistor NM is connected to the ground line VSS of the BPR layer via the top interconnect TOP and the via VIA. The source S of the PMOS transistor PM is connected to the virtual power line VVDD of the BPR layer via the bottom interconnect BTM and the via VIA shared with the drain D of the PMOS transistor PM of the power switch circuit PSW.

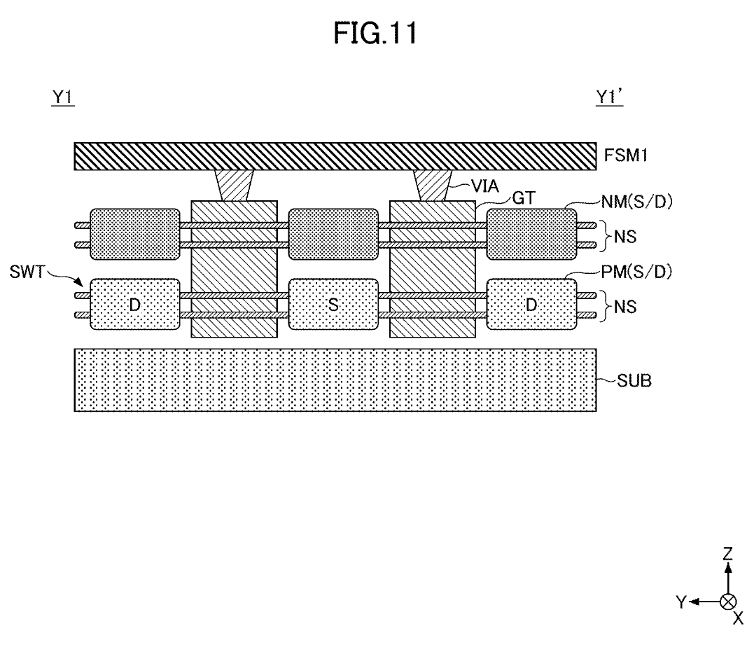

FIG. 11 illustrates an example of a cross-section taken along line Y1-Y1’ of FIGS. 7 and 8. The source/drain region S/D of the NMOS transistor NM is in an open state and the NMOS transistor NM does not function as a transistor. The gate GT of each transistor is connected to an interconnect of the FSM1 layer via a via VIA. Nanosheets NS are respectively formed between the source/drain region S/D of the NMOS transistor NM and between the source/drain region S/D of the PMOS transistor PM.

As described above, in the first embodiment, by connecting the source and the drain of the CFET to the power line TVDD and the virtual power line VVDD formed in the BPR layer on the surface of the substrate SUB, the power switch circuit PSW using the CFET can be appropriately laid out. As a result, the power switch circuit PSW whose circuit scale is suppressed can be mounted on the semiconductor device 100.

### Second Embodiment

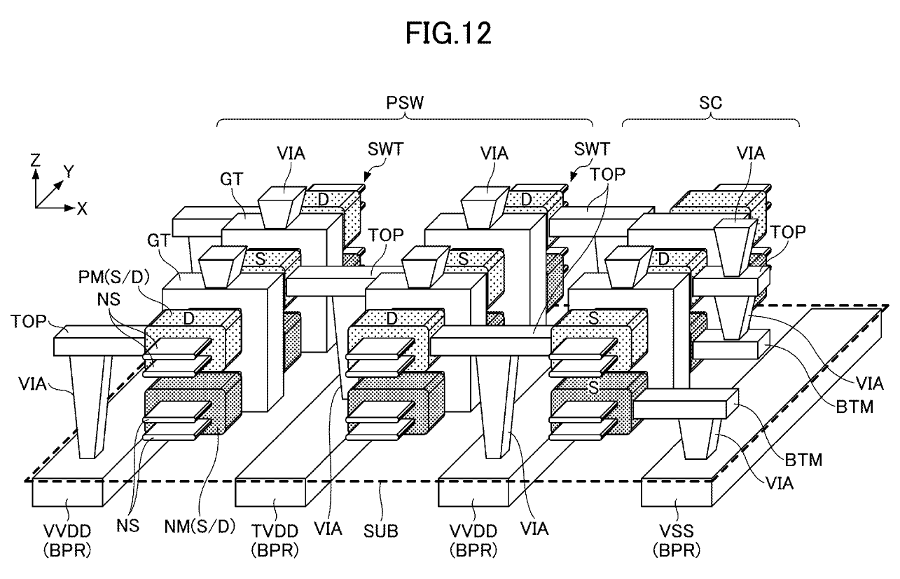

FIG. 12 illustrates an example of a layout of a power switch circuit and a standard cell in a second embodiment. The same elements as those in FIG. 5 are denoted by the same reference numerals, and detailed description thereof will be omitted. For example, a power switch circuit PSW and a standard cell SC illustrated in FIG. 12 are mounted in the standard cell block SCB of the semiconductor device 100, similarly to FIG. 1. The cross-sectional structure of the semiconductor device 100 on which the power switch circuit PSW and the standard cell SC of FIG. 12 are mounted is the same as that of FIG. 2. A circuit disposed in the standard cell block SCB is the same as that of FIG. 3. An example of a circuit of the power switch circuit PSW and the standard cell SC illustrated in FIG. 12 is the same as that of FIG. 4.

FIG. 12 differs from the layout of FIG. 5 in that the positions of the PMOS transistor PM and the NMOS transistor NM in the Z direction are reversed in each CFET with respect to FIG. 5. That is, in FIG. 12, the source/drain regions S/D of the PMOS transistor PM are disposed on the top side, and the source/drain regions S/D of the NMOS transistor NM are disposed on the bottom side.

A drain D of the PMOS transistor PM of the power switch circuit PSW is connected to the virtual power line VVDD of the BPR layer via a top interconnect TOP and a via VIA. Similarly, a source S of the PMOS transistor PM of the power switch circuit PSW is connected to the power line TVDD of the BPR layer via the top interconnect TOP and a via VIA.

In the standard cell SC, a source S of the PMOS transistor PM is connected to the virtual power line VVDD of the BPR layer via the top interconnect TOP and the via VIA shared with the drain D of the PMOS transistor PM of the power switch circuit PSW. In the standard cell SC, a source of the NMOS transistor NM is connected to the ground line VSS of the BPR layer via a bottom interconnect BTM and a via VIA.

In FIG. 12, a virtual power supply line VVDD in a BPR layer located at a boundary between the power switch circuit PSW and the standard cell SC is commonly connected to the power switch circuit PSW and the standard cell SC; however, separate virtual power supply lines VVDD may be provided for the power switch circuit PSW and the standard cell SC. In addition, in the power switch circuit PSW, positions of a power supply line TVDD in the BPR layer and the virtual power supply line VVDD may be interchanged with each other.

As described above, in the second embodiment as well, similarly to the first embodiment, by connecting the source and the drain of the CFET to the power line TVDD and the virtual power line VVDD formed in the BPR layer on the surface of the substrate SUB, the power switch circuit PSW using the CFET can be appropriately laid out. As a result, the power switch circuit PSW whose circuit scale is suppressed can be mounted on the semiconductor device 100.

### Third Embodiment

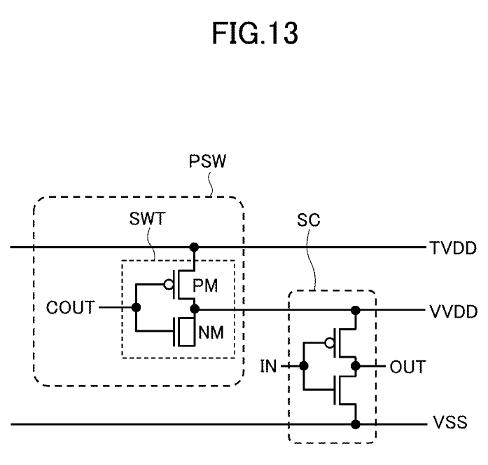

FIG. 13 illustrates an example of a power switch circuit and a standard cell in a third embodiment. The same elements as those in FIG. 4 are denoted by the same reference numerals, and detailed description thereof will be omitted. For example, a power switch circuit PSW and a standard cell SC illustrated in FIG. 13 are mounted in the standard cell block SCB of the semiconductor device 100, similarly to FIG. 1. The cross-sectional structure of the semiconductor device 100 on which the power switch circuit PSW and the standard cell SC of FIG. 13 are mounted is the same as that of FIG. 2. A circuit disposed in the standard cell block SCB is the same as that of FIG. 3. FIG. 13 is the same as the circuit configuration of FIG. 4 except that a source and a drain of an NMOS transistor NM are connected to a virtual power line VVDD.

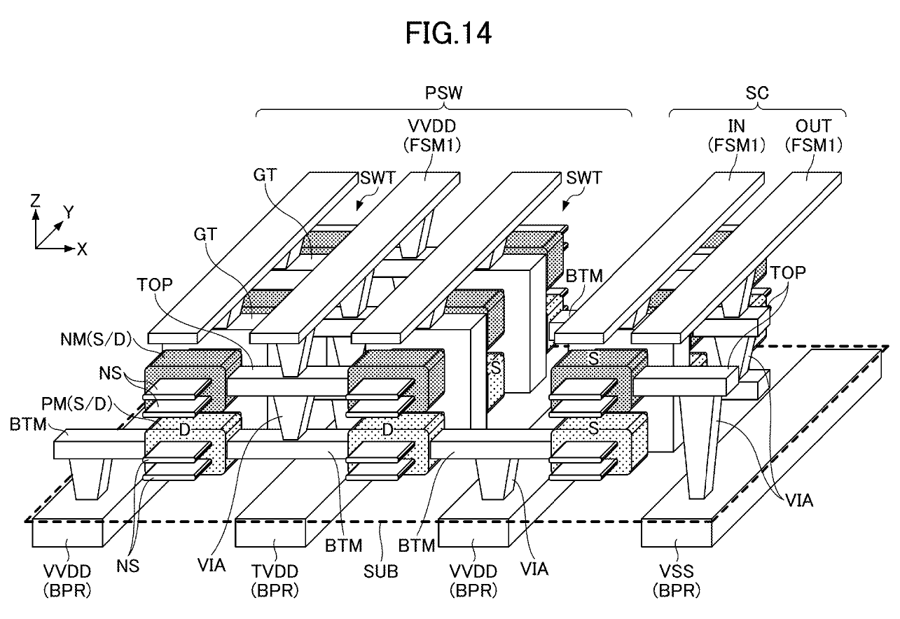

FIG. 14 illustrates an example of a layout of the power switch circuit PSW and the standard cell SC of FIG. 13. The same elements as those in FIG. 5 are denoted by the same reference numerals, and detailed description thereof will be omitted. In FIG. 14, a source/drain region S/D of the NMOS transistor NM of the power switch circuit PSW is connected to the virtual power line VVDD of the FSM1 layer via a top interconnect TOP and a via VIA. Further, a drain D of the PMOS transistor PM of the power switch circuit PSW is connected not only to the virtual power line VVDD of the BPR layer but also to the virtual power line VVDD of the FSM1 layer via a bottom interconnect BTM, a via VIA, a top interconnect TOP, and a via VIA. The layout of the standard cell SC is the same as that of FIG. 5.

In the switch transistor SWT, by connecting the source/drain region S/D of the NMOS transistor NM to the virtual power line VVDD without leaving the source and the drain open, the potential of the source/drain region S/D of the NMOS transistor NM can be stabilized. Accordingly, variation in characteristics of the power switch circuit PSW can be suppressed. In addition, charge/discharge currents (leakage currents) in the source region and the drain region can be suppressed.

Note that as a modified example of the layout of FIG. 14, the positions of the PMOS transistor PM and the NMOS transistor NM in the Z direction may be reversed. That is, the source/drain region S/D of the PMOS transistor PM may be disposed on the top side, and the source/drain region S/D of the NMOS transistor NM may be disposed on the bottom side.

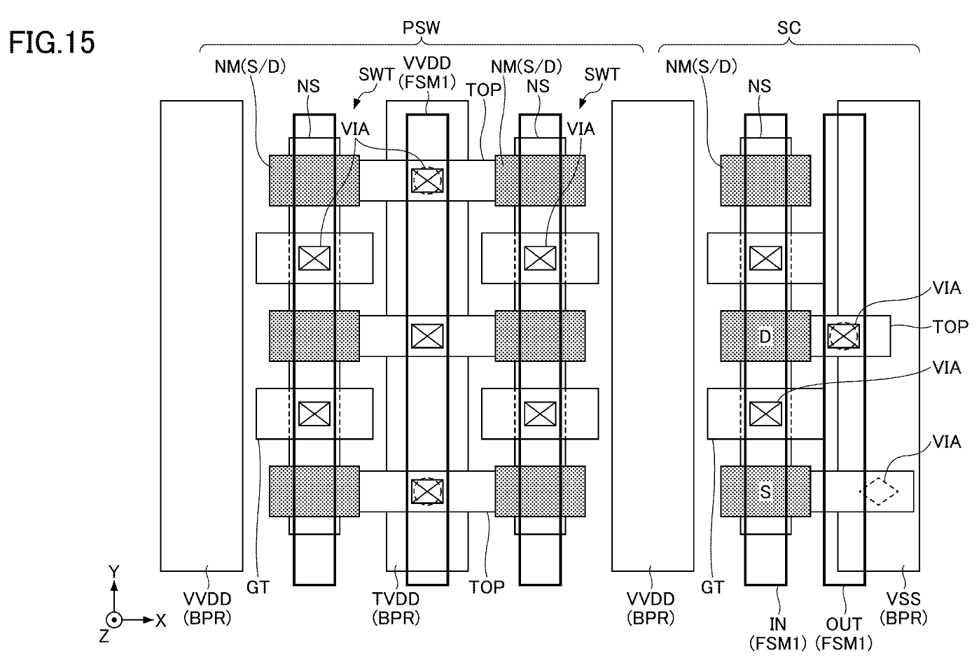

FIG. 15 is a plan view illustrating an example of the substrate SUB viewed from the top interconnect TOP side in the power switch circuit PSW and the standard cell SC of FIG. 14. The same elements as those in FIG. 7 are denoted by the same reference numerals, and detailed description thereof will be omitted.

The source/drain region S/D of the NMOS transistor NM of the switch transistor SWT is connected to the virtual power line VVDD of the FSM1 layer via the top interconnect TOP and the via VIA. The layout of the standard cell SC is the same as that of FIG. 7.

The top interconnect TOP interconnecting the source/drain region S/D of the NMOS transistors NM adjacent in the X direction is an example of a first interconnect or a second interconnect. The virtual power line VVDD of the FSM1 layer connected to the source/drain region S/D of the NMOS transistor NM via the top interconnect TOP and the via VIA is an example of a third interconnect.

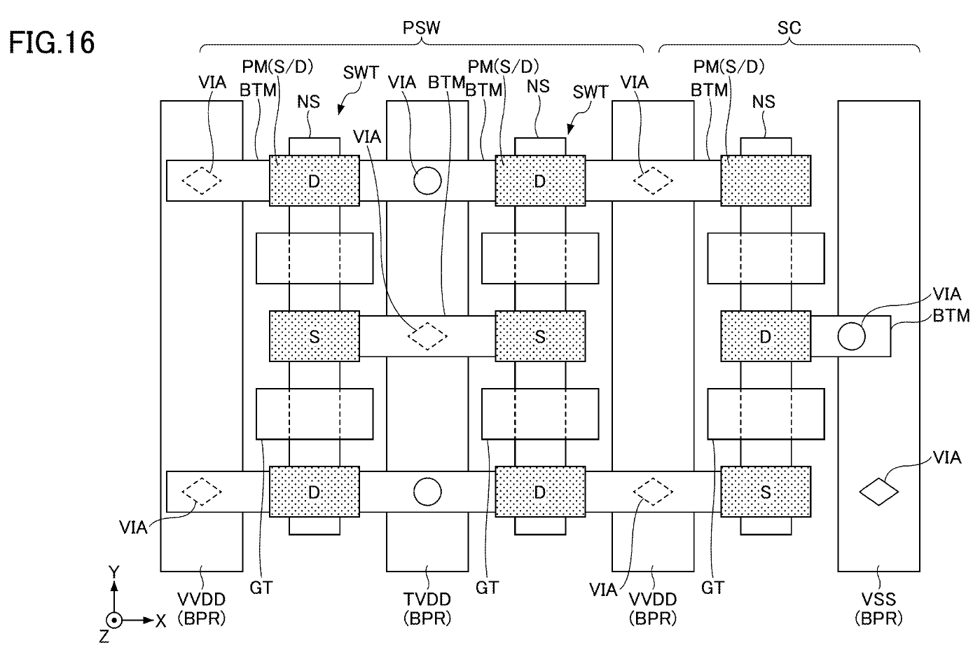

FIG. 16 is a plan view illustrating an example of the substrate SUB side viewed from the bottom interconnect side in the power switch circuit PSW and the standard cell SC of FIG. 14. The same elements as those in FIG. 8 are denoted by the same reference numerals, and detailed description thereof will be omitted.

The drain D of the PMOS transistor PM of the switch transistor SWT is connected to the virtual power line VVDD of the BPR layer via the bottom interconnect BTM and the lower via VIA, and is further connected to the virtual power line VVDD of the FSM1 layer in FIG. 15 via the bottom interconnect BTM and the upper via VIA. The layout of the standard cell SC is the same as that of FIG. 8.

As described above, in the third embodiment as well, similarly to the first and second embodiments, by connecting the source and the drain of the CFET to the power line TVDD and the virtual power line VVDD formed in the BPR layer on the surface of the substrate SUB, the power switch circuit PSW using the CFET can be appropriately laid out. As a result, the power switch circuit PSW whose circuit scale is suppressed can be mounted on the semiconductor device 100.

Furthermore, in the third embodiment, in the switch transistor SWT, by connecting the source and the drain of the NMOS transistor NM to the virtual power line VVDD without leaving the source and the drain open, the potential of the source and the drain of the NMOS transistor NM can be stabilized. Accordingly, variation in characteristics of the switch transistor SWT can be suppressed. In addition, charge/discharge currents (leakage currents) in the source region and the drain region can be suppressed.

### Fourth Embodiment

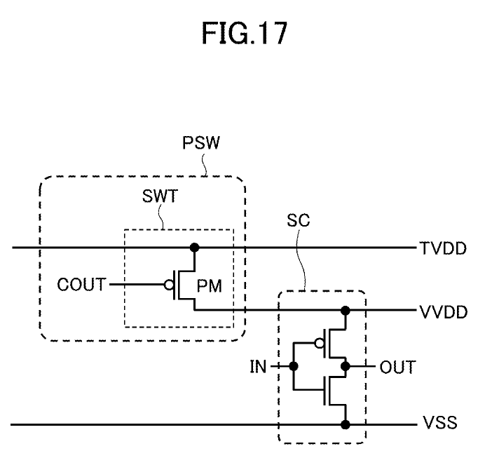

FIG. 17 illustrates an example of a power switch circuit and a standard cell in a fourth embodiment. The same elements as those in FIG. 4 are denoted by the same reference numerals, and detailed description thereof will be omitted. For example, a power switch circuit PSW and a standard cell SC illustrated in FIG. 17 are mounted in the standard cell block SCB of the semiconductor device 100, similarly to FIG. 1. The cross-sectional structure of the semiconductor device 100 on which the power switch circuit PSW and the standard cell SC of FIG. 17 are mounted is the same as that of FIG. 2. A circuit disposed in the standard cell block SCB is the same as that of FIG. 3. FIG. 17 is the same as the circuit configuration of FIG. 4 except that a switch transistor SWT of the power switch circuit PSW does not include an NMOS transistor NM but includes only a PMOS transistor PM.

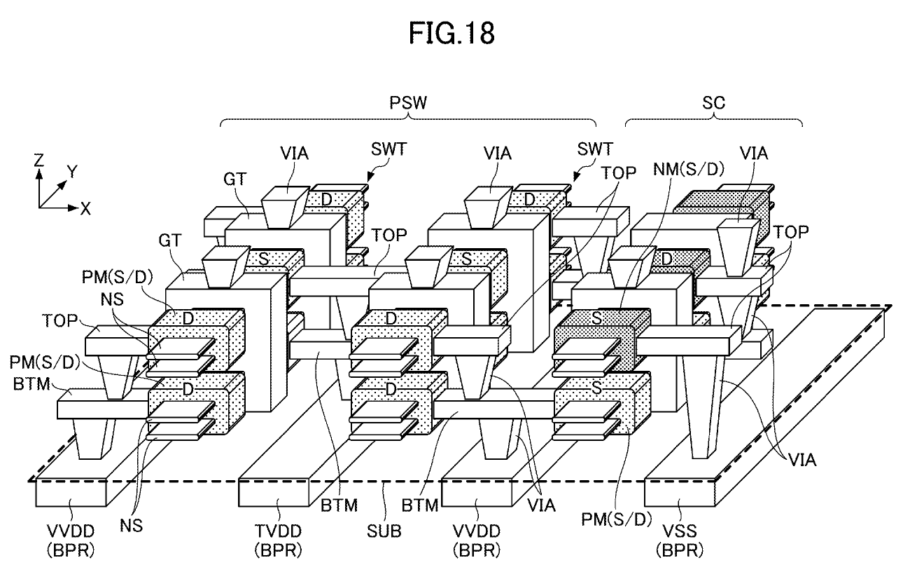

FIG. 18 illustrates an example of a layout of the power switch circuit PSW and the standard cell SC of FIG. 17. The same elements as those in FIG. 5 are denoted by the same reference numerals, and detailed description thereof will be omitted. In FIG. 18, in a layout region of the power switch circuit PSW, a source/drain region S/D of the PMOS transistor PM is formed on both the bottom side and the top side.

Interconnects and the like connected to the source/drain region S/D of the PMOS transistor PM on the bottom side are the same as those in FIG. 5. A source S of the PMOS transistor PM on the top side is connected to the power line TVDD of the BPR layer via a top interconnect TOP and a via VIA, and a bottom interconnect BTM and a via VIA shared with the source S of the PMOS transistor PM on the bottom side.

A drain D of the PMOS transistor PM on the top side is connected to the virtual power line VVDD of the BPR layer via the top interconnect TOP and a via VIA, and the bottom interconnect BTM and a via VIA shared with the drain D of the PMOS transistor PM on the bottom side. Layouts of other elements of the power switch circuit PSW are the same as those in FIG. 5. The layout of the standard cell SC is the same as that of FIG. 8.

As described above, in the fourth embodiment as well, similarly to the first to third embodiments, by connecting the source and the drain of the CFET to the power line TVDD and the virtual power line VVDD formed in the BPR layer on the surface of the substrate SUB, the power switch circuit PSW using the CFET can be appropriately laid out. As a result, the power switch circuit PSW whose circuit scale is suppressed can be mounted on the semiconductor device 100.

Furthermore, in the fourth embodiment, since the source/drain region S/D of the PMOS transistor PM is formed on both the top side and the bottom side of the power switch circuit PSW, a supply capability of the virtual power supply potential VVDD by the power switch circuit PSW can be improved compared to FIG. 5 or the like.

### Fifth Embodiment

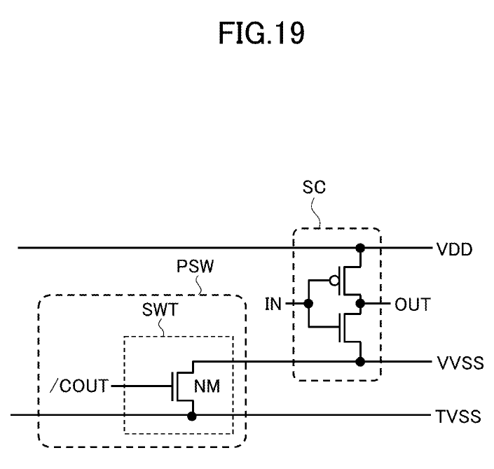

FIG. 19 illustrates an example of a power switch circuit and a standard cell in a fifth embodiment. The same elements as those in FIG. 4 are denoted by the same reference numerals, and detailed description thereof will be omitted. For example, a power switch circuit PSW and a standard cell SC illustrated in FIG. 19 are mounted in the standard cell block SCB of the semiconductor device 100, similarly to FIG. 1. The cross-sectional structure of the semiconductor device 100 on which the power switch circuit PSW and the standard cell SC of FIG. 19 are mounted is the same as that of FIG. 2.

In FIG. 19, a switch transistor SWT of the power switch circuit PSW is formed by an NMOS transistor NM, and each circuit of the standard cell SC is connected to a power line VDD and a virtual ground line VVSS and operates. For example, when an inverter is formed in the standard cell SC, a source of a PMOS transistor of the inverter is connected to the power line VDD, and a source of an NMOS transistor of the inverter is connected to the virtual ground line VVSS.

The switch transistor SWT includes an NMOS transistor NM having a source connected to a ground line TVSS and a drain connected to the virtual ground line VVSS. For example, a gate of the NMOS transistor NM of the switch transistor SWT receives a control signal /COUT, which is a logic inversion of the control signal COUT output from the control circuit CNTL in FIG. 3. The ground line TVSS is an example of a first power line, the virtual ground line VVSS is an example of a second power line, and the power line VDD is an example of a third power line.

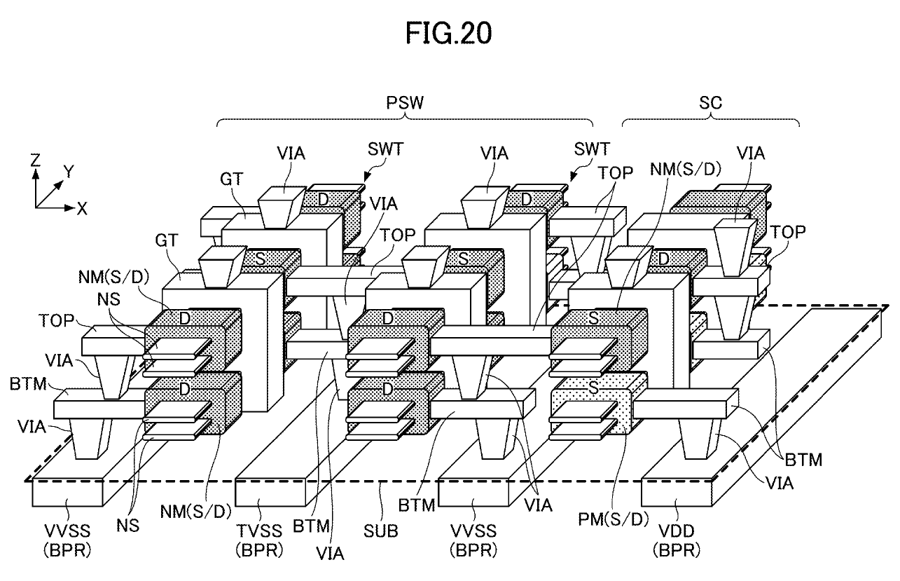

FIG. 20 illustrates an example of a layout of the power switch circuit PSW and the standard cell SC of FIG. 19. The same elements as those in FIG. 5 are denoted by the same reference numerals, and detailed description thereof will be omitted. In FIG. 20, in the layout region of the power switch circuit PSW, a source/drain region S/D of the NMOS transistor NM is formed on both the bottom side and the top side. In the BPR layer, the virtual ground line VVSS, the ground line TVSS, the virtual ground line VVSS, and the power line VDD extending in the Y direction are formed with an interval in the X direction.

A drain D of the NMOS transistor NM on the bottom side is connected to the virtual ground line VVSS of the BPR layer via a bottom interconnect BTM and a via VIA. A source S of the NMOS transistor NM on the bottom side is connected to the ground line TVSS of the BPR layer via the bottom interconnect BTM and a via VIA.

A drain D of the NMOS transistor NM on the top side is connected to the virtual ground line VVSS of the BPR layer via a top interconnect TOP and a via VIA, and the bottom interconnect BTM and a via VIA shared with the drain D of the NMOS transistor NM on the bottom side. A source S of the NMOS transistor NM on the top side is connected to the ground line TVSS of the BPR layer via the top interconnect TOP and a via VIA, and the bottom interconnect BTM and a via VIA shared with the source S of the NMOS transistor NM on the bottom side.

In the standard cell SC, a source of the NMOS transistor is connected to the virtual ground line VVSS of the BPR layer via a top interconnect TOP, a via VIA, a bottom interconnect BTM, and a via VIA shared with the drain D of the NMOS transistor NM of the switch transistor SWT. In the standard cell SC, a drain of the NMOS transistor is connected to an upper layer interconnect (not illustrated) via the top interconnect TOP and an upper via VIA, and is further connected to a bottom interconnect BTM via a lower VIA.

In the standard cell SC, a source of the PMOS transistor is connected to the power line VDD of the BPR layer via the bottom interconnect BTM and the via VIA. In the standard cell SC, a drain of the PMOS transistor is connected to the top interconnect TOP via the bottom interconnect BTM and the via VIA. Note that in the PMOS transistor and the NMOS transistor of the standard cell SC, the gate and the source on the far side in the Y direction in FIG. 20 are set to an open state and are not used.

As described above, in the fifth embodiment, the source and the drain of the CFET provided in the power switch circuit PSW are connected to the ground line TVSS and the virtual ground line VVSS formed in the BPR layer on the surface of the substrate SUB. Further, the source and the drain of the CFET provided in the standard cell SC are connected to the power line VDD and the virtual ground line VVSS formed in the BPR layer on the surface of the substrate SUB.

Accordingly, even in a case of operating while having the switch transistor SWT in which the source is connected to the ground line TVSS and the drain is connected to the virtual ground line VVSS and each circuit of the standard cell SC is connected to the power line VDD and the virtual ground line VVSS, the power switch circuit PSW using the CFET can be appropriately laid out. As a result, the power switch circuit PSW whose circuit scale is suppressed can be mounted on the semiconductor device 100.

Although the present disclosure has been described based on the respective embodiments, the disclosure is not limited to the requirements illustrated in the embodiments. Various modifications may be made without departing from the scope of the disclosure, and components may be appropriately determined according to the application forms thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a substrate;
a first power line, a second power line, and a third power line formed in the substrate;
a first semiconductor layer and a second semiconductor layer formed above the substrate;
a third semiconductor layer formed above the first semiconductor layer;
a fourth semiconductor layer formed above the second semiconductor layer;
a first gate formed between the first semiconductor layer and the second semiconductor layer and between the third semiconductor layer and the fourth semiconductor layer; and
a switch transistor formed between the first power line and the second power line, the switch transistor including the first semiconductor layer, the second semiconductor layer, and the first gate, or including the third semiconductor layer, the fourth semiconductor layer, and the first gate.

2. The semiconductor device according to claim 1,
wherein the switch transistor includes the first semiconductor layer, the second semiconductor layer, and the first gate, and
wherein the third semiconductor layer and the fourth semiconductor layer are electrically interconnected.

3. The semiconductor device according to claim 1, wherein a conductivity type of the first semiconductor layer and the second semiconductor layer is different from a conductivity type of the third semiconductor layer and the fourth semiconductor layer.

4. The semiconductor device according to claim 3, further comprising:
a plurality of the switch transistors, wherein the third semiconductor layer and the fourth semiconductor layer in each of the plurality of the switch transistors are electrically interconnected.

5. The semiconductor device according to claim 4, further comprising:
a first interconnect interconnecting a plurality of the third semiconductor layers adjacent in a second direction different from a first direction in which the first power line, the second power line, and the third power line extend in a plan view;
a second interconnect interconnecting a plurality of the fourth semiconductor layers adjacent in the second direction; and
a third interconnect extending in the first direction in a layer above the first interconnect and the second interconnect, the third interconnect interconnecting the first interconnect and the second interconnect.

6. The semiconductor device according to claim 1, wherein the third semiconductor layer and the fourth semiconductor layer are electrically connected to the second power line.

7. The semiconductor device according to claim 1, further comprising:
a fourth interconnect connected to either the first semiconductor layer or the second semiconductor layer of the switch transistor; and
a standard cell including a PMOS transistor formed between the second power line and the third power line, wherein the fourth interconnect is connected to a source of the PMOS transistor.

8. The semiconductor device according to claim 1, wherein a conductivity type of the first semiconductor layer and the second semiconductor layer is the same as a conductivity type of the third semiconductor layer and the fourth semiconductor layer.
